(19) United States
(12) Patent Application Publication
(10) Pub. No.: US 2013/0049820 A1
(43) Pub. Date: Feb. 28, 2013

(54) CLOCK DIVIDER UNIT

(71) Applicant: Hiroyuki IDE, Shijyonawate City (JP)

(72) Inventor: Hiroyuki IDE, Shijyonawate City (JP)

(73) Assignee: SANYO ELECTRIC CO., LTD., Moriguchi City (JP)

(21) Appl. No.: 13/592,994

(22) Filed: Aug. 23, 2012

(30) Foreign Application Priority Data
Aug. 25, 2011 (JP) 2011-183250

(51) Int. Cl. H03B 19/00

(52) U.S. Cl. 327/115

(57) ABSTRACT

A clock divider unit includes a plurality of divider circuits which divides a common reference clock, and a gate circuit disposed before the plurality of divider circuits. The reference clock is supplied to the divider circuits via the gate circuit after a reset state of each divider circuit is released so that dividing action of each divider circuit is allowed.

### CROSS-REFERENCE TO RELATED APPLICATIONS

This nonprovisional application claims priority under 35 U.S.C. §119(a) on Patent Application No. 2011-183250 filed in Japan on Aug. 25, 2011, the entire contents of which are hereby incorporated by reference.

### BACKGROUND OF THE INVENTION

1. Field of the Invention

The present invention relates to a clock divider unit including a plurality of divider circuits.

2. Description of Related Art

In a circuit using a delay-locked loop (DLL) or other circuit in which relatively strong restriction of clock waveform quality (for example, restriction of a jitter to be substantially small) is imposed, in order to reduce an influence of wirings to jitter as much as possible, a divider circuit generating a clock signal needed for the circuit is disposed as close as possible to the target circuit.

If the divided clock generated by the divider circuit and other clock to be synchronized with the divided clock are used only in the target circuit, a reset circuit used for the divider circuit can be a single asynchronous reset circuit. However, if the divided clock is used also in another circuit that has also relatively strong restriction of waveform quality, a plurality of similar divider circuits are necessary. In this case, if the reset circuit for a plurality of divider circuits is still an asynchronous reset circuit, a clock edge when the reset state is released so that dividing action is started may be different among the plurality of divider circuits.

This will be described with reference to FIGS. 6 and 7. In a clock divider unit of FIG. 6, the same clock and the same reset signal are commonly supplied to a first divider circuit 811 and a second divider circuit 812. A source clock branches at a branch point a and then is supplied to clock input points b and c of the divider circuits 811 and 812. A reset signal branches at a branch point A and then is supplied to reset signal input points B and C of the divider circuits 811 and 812. FIG. 7 is a timing chart of the clock divider unit of FIG. 6. In FIG. 7, rising timings Ta2 to Ta5 of the clock at the branch point a respectively correspond to rising timings Tb2 to Tb5 of the clock at the input point b, and respectively correspond to rising timings Tc2 to Tc5 of the clock at the input point c.

A delayed one of a clock edge 841 corresponds to a clock edge 851, and a delayed one of a clock edge 842 corresponds to a clock edge 852. In FIG. 7, the clock edge 851 indicates a clock edge at the input point b just after the reset state of the divider circuit 811 is released, and the clock edge 852 indicates a clock edge at the input point c just after the reset state of the divider circuit 812 is released. Therefore, the divider circuit 811 starts the dividing action from the clock edge 851 (timing Tb3), while the divider circuit 812 starts the dividing action from the clock edge 852 (timing Tc4). In other words, in the example of FIG. 7, the clock edge corresponding to the start of the dividing action is different between the divider circuits 811 and 812.

In order that the edge of the source clock for starting the dividing action is stably the same among the plurality of divider circuits, it is necessary to adjust wiring delays of the clock and the reset signal so that the timings of the reset signals reaching the individual divider circuits become uniform. In other words, it is necessary to adjust the wiring delays so that the edge of the reset signal reaches between the common neighboring clock edges (for example, so that the edge of the reset signal reaches between the clock edge timings Tb2 and Tb3 for the input point B, and that the edge of the reset signal reaches between the clock edge timings Tc2 and Tc3 for the input point C). A difference T_bc between time T_ab for the source clock to reach from the branch point a to the input point b and time T_ac to reach the input point c is referred to as a clock skew, and a wiring design of controlling the clock skew to be as small as possible is normally performed in a field of digital integrated circuits. It is possible to apply a similar wiring design to the reset signal too, so as to control a difference T_BC between delay time T_AB between points A and B of the reset signal and delay time T_AC between points A and C to be small. However, in the structure of FIG. 6, the reset signal is inherently asynchronous to the clock, and therefore a timing relationship between the reset signal and a clock edge is not defined.

Therefore, although substantially impossible, even if both the delay difference T_bc of the clock and the delay difference T_BC of the asynchronous reset signal can be set to zero, it cannot be assured that the dividing action start timings of the divider circuits 811 and 812 are made uniform in the structure of FIG. 6 using the asynchronous reset system (they may be mostly uniform but may not be uniform depending on timing of the edge of the reset signal).

In view of this, conventionally, there is a countermeasure of synchronizing the reset signal that is asynchronous to the source clock. Specifically, in order to determine a timing relationship between the reset signal and the clock edge, as illustrated in FIG. 8, a synchronizing reset signal generating circuit 813 for synchronizing the reset signal is disposed, so as to generate a synchronizing reset signal for the plurality of divider circuits.

In the clock divider unit of FIG. 8, the source clock branches at the branch point a and then is supplied to input points b, c, and d of the circuit 811, 812, and 813. The asynchronous reset signal is supplied to an input point A of the circuit 813, and a synchronizing reset signal generated by the circuit 813 is output from an output point D to input points B and C of the divider circuits 811 and 812. FIG. 9 is a timing chart of the clock divider unit of FIG. 8. In FIG. 9, the rising timings Ta2 to Tay of the clock at the branch point a correspond to the rising timings Td2 to Td5, Tb2 to Tb5, and Tc2 to Tc5 of the clocks at the input points d, b, and c, respectively. As described above, the delay times T_ad, T_ab, and T_ac between the point a and the point d, b, and c are adjusted by wiring design using clock tree method or the like so that the differences become as small as possible.

The reset signal supplied to the point A of the circuit 813 is synchronized with a rising edge 862 of the source clock supplied to the point d (corresponding to Td3) as illustrated in FIG. 9, for example, and is output from point D. The edge 862 is the same edge as a clock edge 861 (corresponding to Ta3) at the point a.

The reset signal output from the point D is supplied to the input points B and C of the divider circuit 811 with delay times via individual paths (times a little shorter than the delay times T_db3 and T_dc3 in FIG. 9). The reset signal is synchronized with the edge 862 (corresponding to Td3). Therefore, it is possible to perform wiring design including adjustment of delay times T_db3 and T_dc3 so that the reset state of the divider circuits 811 and 812 is released before the timings Tb4 and Tc4 as common edge timing. Thus, it is possible to start the dividing action of the divider circuits 811 and 812 from the common edge timing (timings Tb4 and Tc4 of clock edges 872 of 873 at the input points B and C based on the common edge 871).

Note that there is also proposed a technique to dispose a clock gate before the divider circuit.

Recently, operating frequencies of digital circuits have been increased, and there are many circuits operating at a frequency of a few hundreds megahertz. A frequency of the source clock to be a base of the operation clock at a few hundreds megahertz may reach up to a few giga hertz, and one cycle time of the source clock may be 1 ns or shorter. Further, if a distance between the divider circuits 811 and 812 is increased, it becomes difficult to control the differences (clock skew) among the delay times T_ad, T_ab, and T_ac to be small, and the time from the edge timing Td3 to the edge timing Tb4 or Tc4 (corresponding to T_db4 or T_dc4 in FIG. 9) may be shorter than the clock cycle.

In order to operate the circuit of FIG. 8 as intended, it is necessary to design so as to satisfy a necessary condition that the times T_db3 and T_dc3 are controlled to be shorter than the times T_db4 and T_dc4. However, it may be difficult to perform the wiring design satisfying the necessary condition under the strict constraints as described above.

### SUMMARY OF THE INVENTION

A clock divider unit according to the present invention includes a plurality of divider circuits which divides a common reference clock, and a gate circuit disposed before the plurality of divider circuits, in which the reference clock is supplied to the divider circuits via the gate circuit after a reset state of each divider circuit is released so that dividing action of each divider circuit is allowed.

### BRIEF DESCRIPTION OF THE DRAWINGS

FIG. 1 is a schematic diagram of a clock divider unit according to an embodiment of the present invention.

FIG. 2 is a timing chart of a clock divider unit of FIG. 1.

FIG. 3 is a diagram illustrating an example of an internal structure of a gate circuit of FIG. 1.

FIGS. 4A, 4B, and 4C are diagrams illustrating a delay element, a shift register circuit, and a counter circuit, which can be used for a gate signal generating circuit of FIG. 1.

FIG. 5 is a diagram illustrating a microcomputer that can be used for a clock divider unit of FIG. 1.

FIG. 6 is a diagram illustrating a first example of a structure of a conventional clock divider unit.

FIG. 7 is a timing chart of the clock divider unit of FIG. 6.

FIG. 8 is a diagram illustrating a second example of a structure of a conventional clock divider unit.

FIG. 9 is a timing chart of the clock divider unit of FIG. 8.

### DETAILED DESCRIPTION OF THE PREFERRED EMBODIMENTS

Hereinafter, an example of an embodiment of the present invention will be described specifically with reference to the attached drawings. In the drawings to be referred to, the same part is denoted by the same numeral or symbol so that overlapping description of the same part is omitted as a rule. Note that in this specification, for simple description, when a numeral or a symbol denotes information, a signal, physical quantity, state quantity, a member, or the like, a name of the information, signal, physical quantity, state quantity, member, or the like may be omitted or abbreviated.

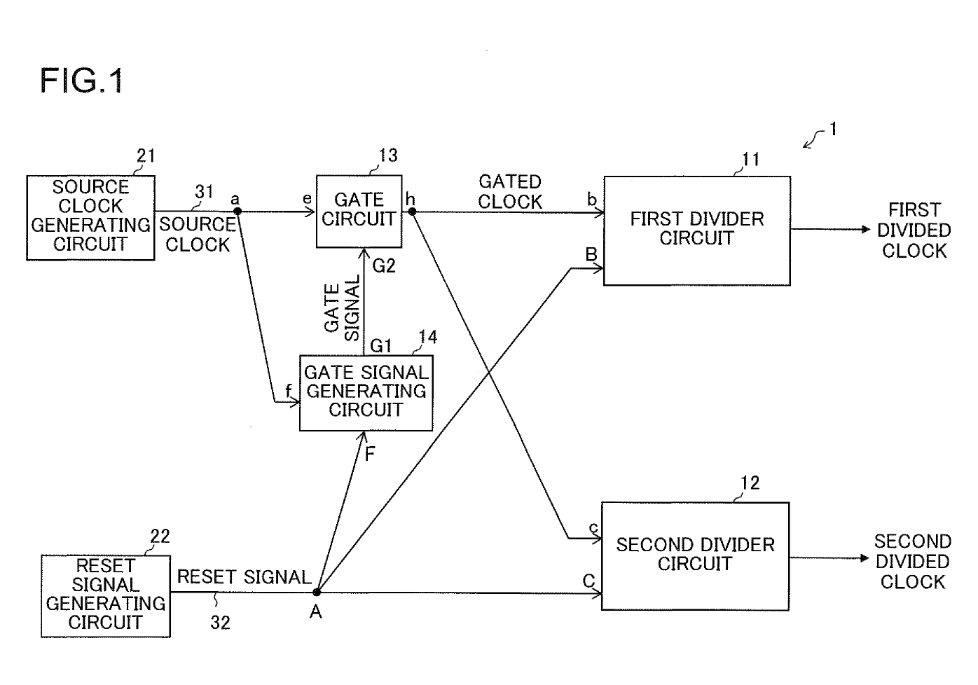

FIG. 1 illustrates a schematic diagram of a clock divider unit (clock divider circuit) 1 according to an embodiment of the present invention. The clock divider unit 1 includes a plurality of divider circuits which divide a common source clock (reference clock), a gate circuit 13 which is disposed before the divider circuits and controls whether or not to output the source clock to the divider circuits in accordance with a gate signal, and a gate signal generating circuit 14 which generates a gate signal. The clock divider unit 1 may further include a source clock generating circuit 21 which generates and outputs a source clock, and a reset signal generating circuit 22 which generates and outputs a reset signal. The number of the divider circuits may be three or larger, but it is supposed here that two divider circuits are disposed, which are a first divider circuit 11 and a second divider circuit 12.

The source clock output from the source clock generating circuit 21 propagates in a common wiring 31 between the circuit 21 and the circuits 13 and 14, and then branches at a branch point a to be supplied to clock input points e and f of the circuits 13 and 14. The reset signal output from the reset signal generating circuit 22 propagates in a common wiring 32 between the circuit 22 and the circuits 11, 12, and 14, and then branches at a branch point A to be supplied to reset signal input points B, C, and F of the circuits 11, 12, and 14. The gate signal generating circuit 14 outputs the gate signal from an output point G1, and the gate signal is supplied to an input point G2 of the gate circuit 13. The gate circuit 13 is a clock gate circuit which controls whether or not to output the source clock supplied to the input point e from an output point h in accordance with the gate signal supplied to the input point G2. Therefore, the source clock output from the output point h is referred to as a gated clock. The gated clock output from the output point h of the gate circuit 13 is supplied to a clock input point b of the divider circuit 11 and a clock input point c of the divider circuit 12 via a wiring between the circuits 13 and 11 and a wiring between the circuits 13 and 12. Hereinafter, the source clock or the gated clock may be simply referred to as a clock.

The reset signal is a voltage signal for controlling whether or not to reset the divider circuits, and has a voltage level of high or low level. The low-level reset signal functions as a reset instruction signal for resetting the divider circuit so as to stop the dividing action of the divider circuit. The high-level reset signal functions as a reset release signal for releasing the reset state of the divider circuit so as to allow the dividing action of the divider circuit.

Therefore, when the low-level reset signal is supplied to the input point B of the divider circuit 11, the divider circuit 11 is reset so that the dividing action of the divider circuit 11 is stopped. When a level of the reset signal at the input point B is switched from the low level to the high level, the reset state of the divider circuit 11 is released, and the divider circuit 11 starts the dividing action at the next rising edge of the clock supplied to the clock input point b. The same is true for the divider circuit 12. The clock is a rectangular wave, and the rising edge of the clock means a change from the low level to the high level of the clock voltage level, or the timing of the change. The same is true for the rising edge of the reset signal. In addition, the rising edge of the clock is simply referred to as a clock edge.

When the dividing action is performed, the divider circuits 11 and 12 respectively divide the source clock supplied as the gated clock from the gate circuit 13 to the input points b and c and output first and second divided signals obtained by the dividing action.

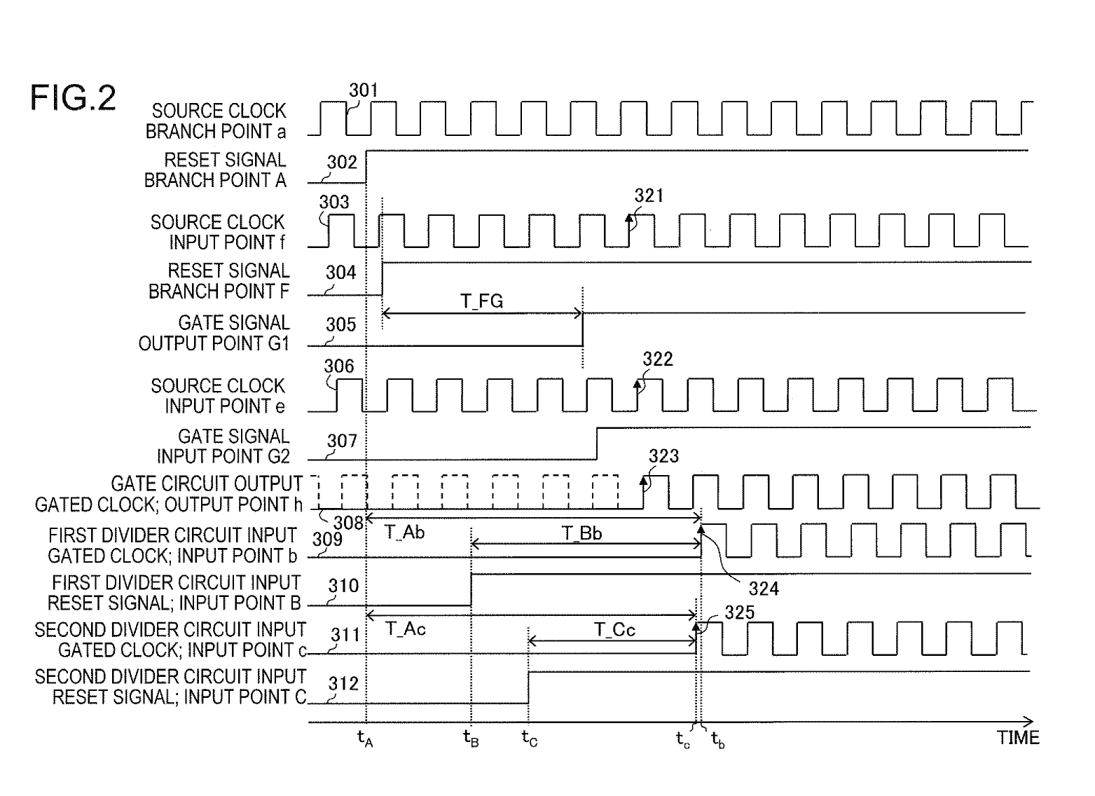

FIG. 2 is a timing chart of the clock divider unit 1. With reference to FIG. 2, a timing relationship in the vicinity of the start time point of the dividing action will be described. In FIG. 2, full line waveforms 301 to 312 are signal waveforms at the points a, A, f, F, G1, e, G2, h, b, B, c, and C, respectively. Note that the broken line like a rectangular wave assigned to the full line waveform 308 is shown for convenience sake and is not a real waveform at the point h. In the example of FIG. 2, the reset signal at the branch point A is switched from the low level to the high level at the timing t_{A}, and then is maintained to be the high level (see waveform 302). The reset signal at the branch point A appears at the input point F after the delay time in the wiring between the points A and F (see waveform 304).

The gate signal generating circuit 14 delays the reset signal received at the input point F by a predetermined time T_FG and outputs the delayed reset signal as the gate signal from the output point G1 (see waveform 305). In the example of FIG. 2, the gate signal generating circuit 14 delays the reset signal received at the input point F by four cycles (four periods) of the source clock based on the source clock supplied to the input point f so that the gate signal is obtained. In other words, for example, the gate signal generating circuit 14 counts the number of the clock edges at the input point f after the rising edge of the reset signal at the input point F, switches the gate signal at the output point G1 from the low level to the high level when the counted number reaches four, and then maintains the gate signal at the output point G1 to be high level. As a matter of course, the delay amount in the gate signal generating circuit 14 may be other than four cycles.

In FIG. 2, arrows 321 to 323 indicate common clock edges, and clock edges 322 and 323 are the delayed ones of the clock edge 321. After the gate signal is switched to the high level at the input point G2, the gate circuit 13 outputs the source clock at the input point e as the gated clock from the output point h, from the next rising edge (322) of the source clock at the input point e. As a result, the gated clock as an output of the gate circuit 13 becomes active after 5 cycles (5 periods) of the source clock from the rising edge of the reset signal at the branch point A (reset release instruction).

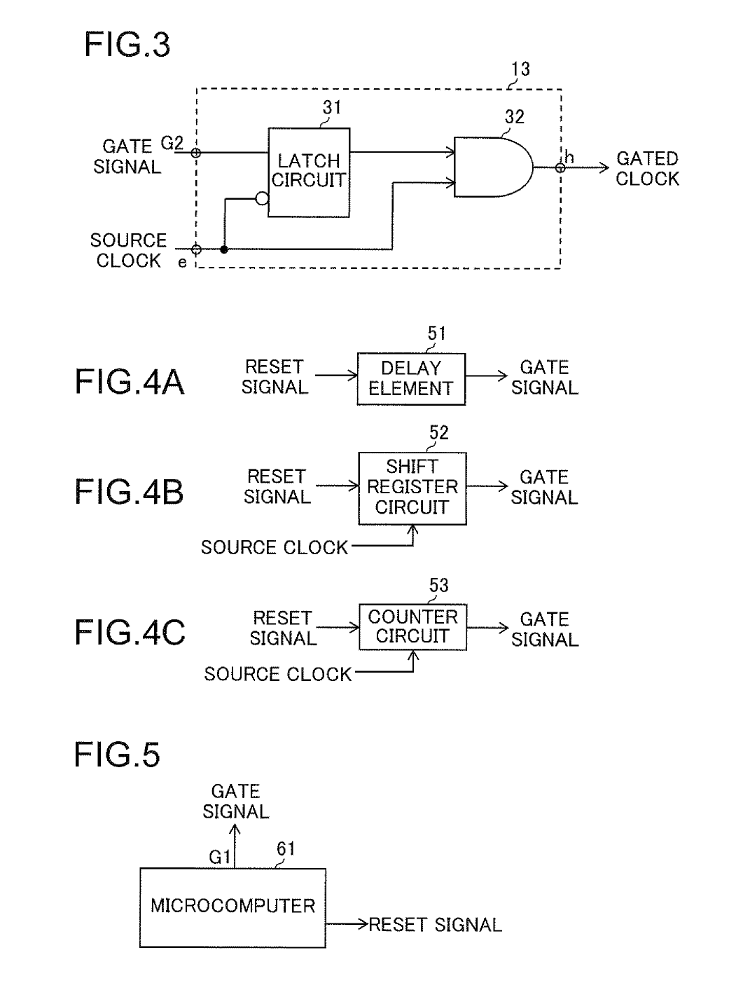

For in stance, the gate circuit 13 receives the gate signal by a low-active latch circuit, activates the gate signal in a low level period of the source clock, and turns on and off the gate between the input point e and the output point h while controlling so that no Glitch noise is generated. More specifically, for example, as illustrated in FIG. 3, the gate circuit 13 can be constituted of a latch circuit 31 and an AND circuit (logical conjunction circuit) 32. The latch circuit 31 latches the gate signal at the input point G2 when the source clock level at the input point e is the low level, and supplies the latched gate signal to the first input point of the AND circuit 32. The source clock to the input point e is supplied to the second input point of the AND circuit 32. The AND circuit 32 outputs a signal indicating the logical conjunction of signals to the first and second input points as a gated clock from the output point h.

On the other hand, at timing t_{B} when the delay time corresponding to the wiring between the points A and B passes after the timing t_{A}, the reset signal at the input point B is switched from the low level to the high level (see waveform 310), and thus the reset state of the divider circuit 11 is released so that the dividing action of the divider circuit 11 can be performed (so that the dividing action of the divider circuit 11 is allowed). Similarly, at timing t_{C} when the delay time corresponding to the wiring between the points A and C passes after the timing t_{A}, the reset signal at the input point C is switched from the low level to the high level (see waveform 312), and thus the reset state of the divider circuit 12 is released so that the dividing action of the divider circuit 12 can be performed (so that the dividing action of the divider circuit 12 is allowed).

However, at the timings t_{B} and t_{C}, the gated clock is not active yet (namely, the source clock is not output as the gated clock from the gate circuit 13). Therefore, the divider circuit 11 does not start the dividing action at the timing t_{B}, and the divider circuit 12 does not start the dividing action at the timing t_{C}. Thus, the divider circuits 11 and 12 wait an input of the clock.

The divider circuits 11 and 12 respectively start the dividing action at first clock edges 324 and 325 (corresponding to the timings t_{b} and t_{c}) after the gated clock becomes active. In other words, the divider circuit 11 starts the dividing action at the timing t_{b}, and the divider circuit 12 starts the dividing action at the timing t_{c}. The timing t_{b} is a timing of the first rising edge 324 of the gated clock supplied to the input point b, and the timing t_{c} is a timing of the first rising edge 325 of the gated clock supplied to the input point c. In FIG. 2, the arrows 321 to 325 indicate common clock edges, and the clock edges 324 and 325 are the delayed ones of the clock edge 323. Note that in FIG. 2, T_Ab indicates time between the timings t_{A} and t_{b}, and T_Ac indicates time between the timings t_{A} and t_{c}.

Although different from the situation illustrated in FIG. 2, if the timings t_{B} and t_{C} at which the reset states of the divider circuits 11 and 12 are released are later than the timings t_{b} and t_{c}, or if the time T_Bb from the timing t_{B} to the timing t_{b} and the time T_Cc from the timing t_{C} to the timing t_{c} are shorter than a recovery time of a flip-flop used in the divider circuits 11 and 12, it is not secured to start operation of the divider circuits 11 and 12 from the first clock edge after the gated clock becomes active. In view of this, the clock divider unit 1 delays the reset signal by the time necessary for securing the start (for example, by a few cycle of the source clock), and the gated clock obtained by using the delay is commonly supplied to the divider circuits 11 and 12. Therefore, the time T_Bb and the time T_Cc can be sufficiently secured. In the opposite concept, it is preferred to determine the delay time T_FG in the gate signal generating circuit 14 so that the timings t_{B} and t_{C} are respectively earlier than the timings t_{b} and t_{c}, and that the times T_Bb and T_Cc are longer than the recovery time of the flip-flop used in the divider circuits 11 and 12.

As described above, in this embodiment, the source clock (gated clock) is supplied to the divider circuits via the gate circuit 13 after the reset state of each divider circuit is released so that the dividing action of each divider circuit is allowed (namely, after the timings t_{B} and t_{C}). Therefore, the divider circuits 11 and 12 can securely start the dividing action from the same clock edge (324 and 325) of the source clock. By setting the time after the reset state of each divider circuit is released until the gate circuit 13 is opened (the time after the reset state of each divider circuit is released until the start of output of the source clock from the output point h) to be sufficiently long, it is possible to design wirings under a loose restriction condition, even though the source clock has high frequency. In other words, it is possible to easily design a circuit having a synchronization relationship for a plurality of divider circuits to start operations from the same clock edge, with respect to a high-frequency source clock.

The gate signal generating circuit 14 is further described below. In the gate signal generating circuit 14 of FIG. 1, the gate signal is generated by delaying the reset signal supplied to the input point F. Then, the clock divider unit 1 controls, by using the gate signal, the timing when the source clock is supplied to the divider circuits 11 and 12 via the gate circuit 13, and thus the source clock is supplied to the divider circuits after the reset state of each divider circuit is released.

The gate signal generating circuit 14 can use an arbitrary element or circuit in order to delay the reset signal and obtain the gate signal. For instance, the gate signal generating circuit 14 can be constituted using a delay element 51, a shift register circuit 52, or a counter circuit 53 (see FIGS. 4A, 4B, and 4C).

The delay element 51 delays the reset signal supplied to the input point F by the predetermined time T_FG, and outputs the delayed reset signal as the gate signal from the output point G1. The delay element 51 can be constituted using a simple wire. In this case, it is not necessary to supply the source clock to the gate signal generating circuit 14. However, it is possible to constitute the delay element 51 realizing the above-mentioned delay by using the source clock (in this case, the delay element 51 can be one type of the shift register circuit 52). When the shift register circuit 52 and the counter circuit 53 are used, the reset signal is delayed by using the source clock so that the gate signal is generated. If the delay of four cycles (four periods) of source clock is performed as the example of FIG. 2, it is preferred to constitute the shift register circuit 52 by connecting four stages of flip-flop circuits in series so as to operate based on the source clock, or to constitute the counter circuit 53 of three or larger bits, which counts the cycle number of the source clock.

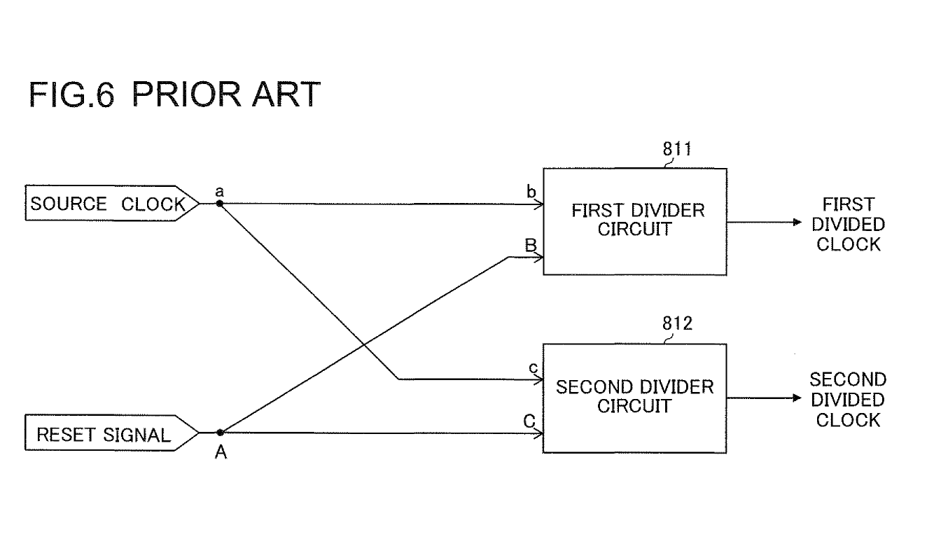

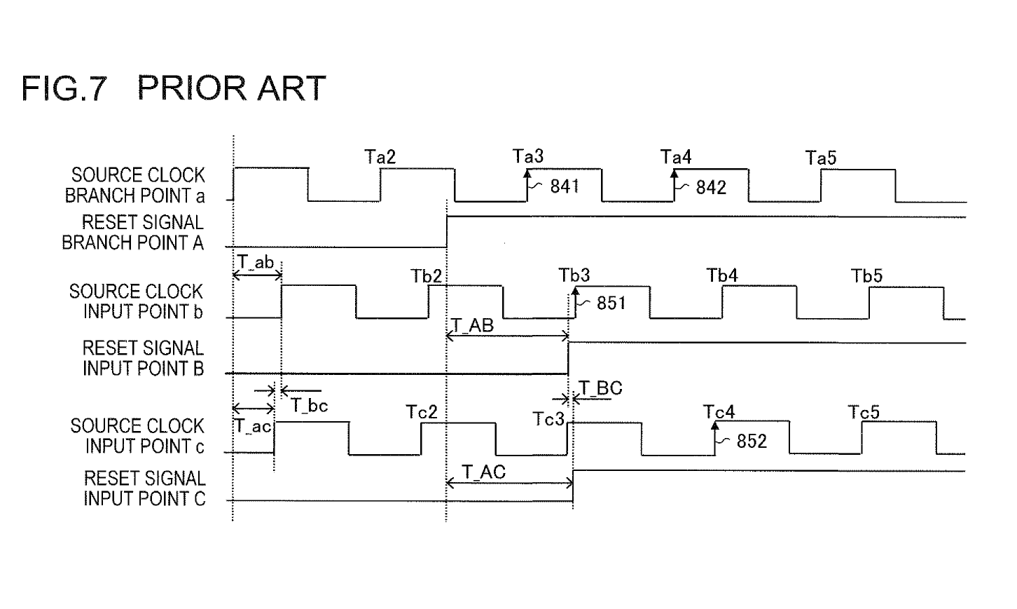

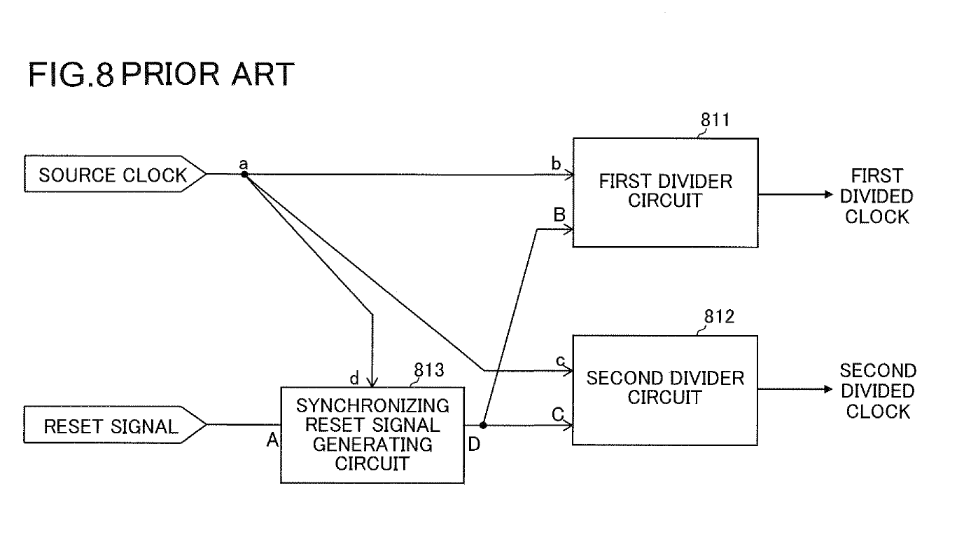

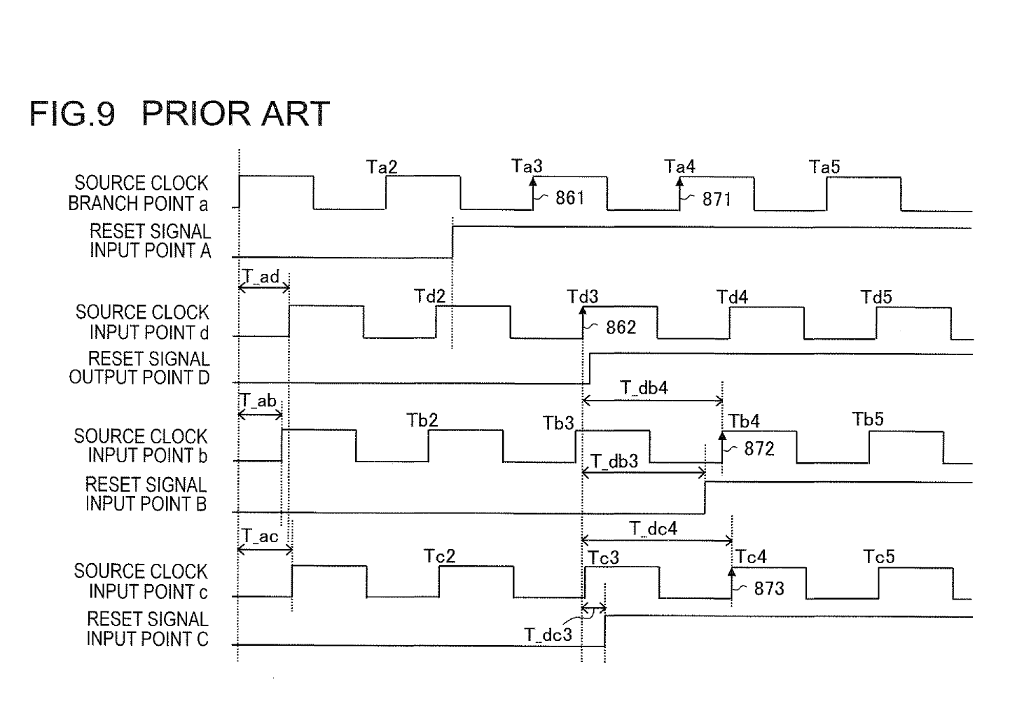

It is possible to generate the gate signal under control of software. For instance, in the clock divider unit 1, it is possible to dispose a microcomputer 61 illustrated in FIG. 6 instead of the gate signal generating circuit 14. The microcomputer 61 includes the reset signal generating circuit 22 illustrated in FIG. 1, and outputs the reset signal to the input points B and C via the common wiring 32 and the branch point A under control of software working on the microcomputer 61. On the other hand, the microcomputer 61 also includes a function of the gate signal generating circuit 14 and outputs the gate signal to the input point G2 of the gate circuit 13 from the output point G1 of the microcomputer 61 independently of the reset signal under control of the above-mentioned software.

It is not always necessary to supply the source clock to the microcomputer 61 (the gate signal generating circuit in the microcomputer 61), and it is sufficient to generate and output the gate signal in accordance with the reset signal so that a timing relationship similar to FIG. 2 is realized (to generate and output a delayed signal of the reset signal as the gate signal). In other words, the microcomputer 61 can switch the voltage level of the gate signal at the output point G1 from the low level to the high level after the predetermined time T_FG from the time point when the voltage level of the reset signal output by itself is switched from the low level to the high level. Note that it is possible to output the reset signal to the divider circuits 11 and 12 from a reset signal generating circuit other than the microcomputer 61.

The embodiment of the present invention can be appropriately modified variously in the scope of the technical concept described in claims. The above-mentioned embodiment is merely an example of embodiment of the present invention, and meanings of the present invention and elements thereof are not limited to those described in the above-mentioned embodiment. Specific values shown in the above description are merely examples, which can be changed to various values as a matter of course.

The relationship between the low level and the high-level of each signal may be opposite. The clock divider unit 1 can be mounted in an arbitrary digital circuit and an arbitrary apparatus including the digital circuit (for example, an image pickup apparatus such as a digital camera, a personal computer, and a mobile terminal such as a mobile phone).

What is claimed is:

1. A clock divider unit comprising:
a plurality of divider circuits which divides a common reference clock; and
a gate circuit disposed before the plurality of divider circuits, wherein
the reference clock is supplied to the divider circuits via the gate circuit after a reset state of each divider circuit is released so that dividing action of each divider circuit is allowed.

2. The clock divider unit according to claim 1, further comprising a gate signal generating circuit which generates a gate signal in accordance with a reset signal for controlling whether or not to reset each divider circuit and outputs the gate signal to the gate circuit, wherein
the clock divider unit controls the timing when the reference clock is supplied to each divider circuit via the gate circuit by using the gate signal so as to supply the reference clock to each divider circuit after the reset state of each divider circuit is released.

3. The clock divider unit according to claim 2, wherein the gate signal generating circuit generates a delayed signal of the reset signal as the gate signal.

4. The clock divider unit according to claim 3, wherein the gate signal generating circuit generates the gate signal by delaying the reset signal supplied to itself by using a delay element, a shift register circuit, or a counter circuit.
